(19) United States
(12) Patent Application Publication
(10) Pub. No.: US 2020/0075482 A1
(43) Pub. Date: Mar. 5, 2020

(54) SEMICONDUCTOR DEVICE AND MANUFACTURING METHOD THEREOF

(71) Applicant: WUHAN XINXIN SEMICONDUCTOR MANUFACTURING CO., LTD., Wuhan (CN)

(72) Inventor: Guoliang YE, Wuhan (CN)

(21) Appl. No.: 16/393,223

(22) Filed: Apr. 24, 2019

(30) Foreign Application Priority Data
Aug. 28, 2018 (CN) 201810990664.5

(51) Int. Cl. H01L 23/522; H01L 25/065; H01L 21/768; H01L 21/762; H01L 29/06; H01L 23/48

(52) U.S. Cl. CPC H01L 23/5226; H01L 25/0657; H01L 21/76898; H01L 23/481; H01L 21/76832; H01L 21/762; H01L 29/0649; H01L 21/76802

(57) ABSTRACT

A semiconductor device and a manufacturing method thereof are disclosed. Two etching processes are used to form openings above a first wafer metal layer and a second wafer metal layer respectively in different regions, a substrate on the upper first wafer is exposed at the two openings, the exposed portion is etched such that the sidewall of the substrate at the exposed portion is etched inward, and an interconnection layer is formed to be respectively electrically connected to the metal layers of the two wafers, thereby realizing the metal interconnection of the two wafers. The device adopts etching to recess the exposed substrate of the first wafer inward, to effectively prevent the isolation layer from being damaged during the subsequent dry etching process and ensure that the isolation layer has a function of isolating the interconnection layer in the subsequent process, thereby improving the yield and performance of the device.

### CROSS-REFERENCE TO RELATED APPLICATION

This application claims the priority of Chinese patent application number 201810990664.5, filed on Aug. 28, 2018, the entire contents of which are incorporated herein by reference.

### TECHNICAL FIELD

The present invention pertains to the technical field of integrated circuit manufacturing, and in particular, relates to a semiconductor device and a manufacturing method thereof.

### BACKGROUND

TSV (Through Silicon Via) technology is a new technology for interconnecting chips by fabricating vertical conduction between a chip and a chip and between a wafer and a wafer, which enables a higher stack density in three dimensions.

In the TSV process, after the two wafers are bonded, in order to realize the metal layer interconnection between the wafers, a deep hole penetrating the upper wafer and a part of the lower wafer is formed, and after an isolation layer is deposited, the deep hole is filled with an interconnection layer. Thus, the interconnection between the metal layer of the lower wafer and the metal layer of the upper wafer can be achieved through the interconnection layer. However, in actual production, it is found that the substrate of the upper wafer is easily damaged, thereby affecting the yield and performance of the device on the wafer.

### SUMMARY OF THE INVENTION

An objective of the present invention is to provide a semiconductor device and a manufacturing method thereof to enhance the yield and performance of the device on the wafer.

In order to solve the above technical problems, the present invention provides a manufacturing method of a semiconductor device, including:

providing a first wafer and a second wafer, wherein the first wafer includes a first substrate, a first dielectric layer formed on the first substrate and a first metal layer embedded in the first dielectric layer, the second wafer includes a second substrate, a second dielectric layer formed on the second substrate and a second metal layer embedded in the second dielectric layer, and the first dielectric layer and the second dielectric layer being bonded to each other;

forming a first opening, wherein the first opening penetrates through the first substrate and a portion of the first dielectric layer, the first opening located above the first metal layer, and the first substrate being exposed at the first opening;

forming a second opening, wherein the second opening penetrates through the first substrate, the first dielectric layer and a portion of the second dielectric layer, the second opening located above the second metal layer, and the first substrate being exposed at the second opening;

forming recessed portions, wherein the recessed portions are located at an exposed portion of the first substrate at the second opening;

forming an isolation layer, wherein the isolation layer covers surfaces of the recessed portions, a surface of the first opening and a surface of the second opening;

performing a dry etching process to expose a portion of the first metal layer below the first opening and a portion of the second metal layer below the second opening; and

forming an interconnection layer, wherein the interconnection layer is electrically connected to the first metal layer via the first opening and electrically connected to the second metal layer via the second opening.

The present invention provides a semiconductor device, including:

a first wafer and a second wafer, wherein the first wafer includes a first substrate, a first dielectric layer formed on the first substrate and a first metal layer embedded in the first dielectric layer, the second wafer includes a second substrate, a second dielectric layer formed on the second substrate and a second metal layer embedded in the second dielectric layer, and the first dielectric layer and the second dielectric layer being bonded to each other;

a first opening and a second opening, wherein the first opening penetrates through the first substrate and a portion of the first dielectric layer, the first opening is located above the first metal layer, and the first substrate being exposed at the first opening; and the second opening penetrates through the first substrate, the first dielectric layer and a portion of the second dielectric layer, the second opening is located above the second metal layer, and the first substrate being exposed at the second opening;

recessed portions, wherein the recessed portions are located at an exposed portion of the first substrate at least at one of the first opening and the second opening;

an isolation layer, wherein the isolation layer covers surfaces of the recessed portions, a surface of the first opening and a surface of the second opening; and

an interconnection layer formed in the first opening and the second opening, wherein the interconnection layer is electrically connected to the first metal layer via the first opening and electrically connected to the second metal layer via the second opening.

Optionally, the first substrate is recessed toward the two sides of the first opening at the exposed portion of the first opening.

Optionally, the longitudinal section of the recessed portion of the first substrate at the exposed portion has an arcuate shape.

According to the present invention, after the second opening is formed, the first substrate exposed by the second opening is etched such that the exposed first substrate is recessed toward the two sides of the second opening, and then an isolation layer covering the sidewall of the second opening and the recessed portion is formed to effectively prevent the isolation layer from being damaged during the subsequent dry etching process and ensure that the isolation layer has a function of isolating the interconnection layer in the subsequent process, thereby improving the yield and performance of the device.

### BRIEF DESCRIPTION OF THE DRAWINGS

FIG. 1 is a schematic cross-sectional view after two wafers are bonded and after a deep hole is formed;

FIG. 2 is a schematic cross-sectional view after an isolation layer is formed;

FIG. 3 is a schematic cross-sectional view after a metal layer on the bottom of the deep hole is exposed;

FIG. 4 is a schematic cross-sectional view after an interconnection layer is formed;

FIG. 5 is a flow diagram of a manufacturing method of a semiconductor device according to an embodiment of the present invention;

FIG. 6 is a schematic cross-sectional view after two wafers are bonded according to an embodiment of the present invention;

FIG. 7 is a schematic cross-sectional view after a first opening is formed according to an embodiment of the present invention;

FIG. 8 is a schematic cross-sectional view after the first opening is filled according to an embodiment of the present invention;

FIG. 9 is a schematic cross-sectional view after a second opening is formed according to an embodiment of the present invention;

FIG. 10 is a schematic cross-sectional view of removing a photoresist layer according to an embodiment of the present invention;

FIG. 11 is a schematic cross-sectional view after a first substrate is etched at an exposed portion of a second opening according to an embodiment of the present invention;

FIG. 12 is a schematic cross-sectional view after a filling layer in the first opening is removed according to an embodiment of the present invention;

FIG. 13 is a schematic cross-sectional view after a metal interconnection of an interconnection layer is formed according to an embodiment of the present invention;

FIG. 14 is a schematic cross-sectional view after a filling layer in the first opening is removed according to another embodiment of the present invention;

FIG. 15 is a schematic cross-sectional view after the first substrate is etched at the exposed portions of the first opening and the second opening according to another embodiment of the present invention; and

FIG. 16 is a schematic cross-sectional view after a metal interconnection of an interconnection layer is formed according to another embodiment of the present invention.

The reference signs are as follows:
10—upper wafer;
101—first substrate; 102—first dielectric layer; 104—first etching stopping layer; 102a—first dielectric layer first portion; 102b—first dielectric layer second portion;
105—oxide layer; 106—isolation layer; 107—interconnection layer;
20—lower wafer;
201—second substrate; 202—second dielectric layer; 203—second metal layer;
204—second etching stopping layer 204; 202a—second dielectric layer first portion; 202b—second dielectric layer second portion;
30—bonding interface;
40—deep hole;
50—first wafer;
501—first substrate; 502—first dielectric layer; 503—first metal layer; 504—first etching stopping layer;
502a—first dielectric layer first portion; 502b—first dielectric layer second portion;
505—oxide layer; 506—patterned photoresist layer; 507—isolation layer;
60—second wafer;
601—second substrate; 602—second dielectric layer; 603—second metal layer;
604—second etching stopping layer;
602a—second dielectric layer first portion; 602b—second dielectric layer second portion;
70—bonding interface;
81—first opening; 82—second opening;
91—filling layer; 92—interconnection layer.

### DETAILED DESCRIPTION OF THE INVENTION

As described in the background, the isolation layer deposited on the exposed portion of the substrate of the upper wafer is easily damaged in the subsequent dry etching process to damage the substrate, thereby affecting the yield and performance of the device on the wafer.

With reference to FIGS. 1-4, a method of metal interconnection after two wafers are bonded is described.

First, as shown in FIG. 1, the upper wafer 10 and the lower wafer 20 are bonded to form a bonding interface 30, wherein the upper wafer 10 is in an inverted state.

The upper wafer 10 includes a first substrate 101, a first dielectric layer 102 and a first metal layer (not shown). The lower wafer 20 includes a second substrate 201, a second dielectric layer 202 and a second metal layer 203, and the first dielectric layer 102 faces the second dielectric layer 202. The first dielectric layer 102 includes a first dielectric layer first portion 102a and a first dielectric layer second portion 102b. The second dielectric layer 202 includes a second dielectric layer first portion 202a and a second dielectric layer second portion 202b. The second metal layer 203 is embedded in the second dielectric layer first portion 202a and the second dielectric layer second portion 202b. The upper wafer 10 further includes a first etching stopping layer 104, and the first etching stopping layer 104 is located between the first dielectric layer first portion 102a and the first dielectric layer second portion 102b. The lower wafer 20 further includes a second etching stopping layer 204, and the second etching stopping layer 204 is located between the second metal layer 203 and the second dielectric layer second portion 202b. Optionally, the upper wafer 10 further includes an oxide layer 105 located on the back surface of the first substrate 101.

Then, a photolithography and etching process is performed, the etching process terminating at the second etching stopping layer 204, to form a deep hole 40. The deep hole 40 penetrates through the oxide layer 105, the first substrate 101, the first dielectric layer 102 and a portion of the thickness of the second dielectric layer 202, and is located above the second metal layer 203. The first substrate 101 forms exposed portions 101a and 101b (shown at the circles in FIG. 1) at the deep hole 40.

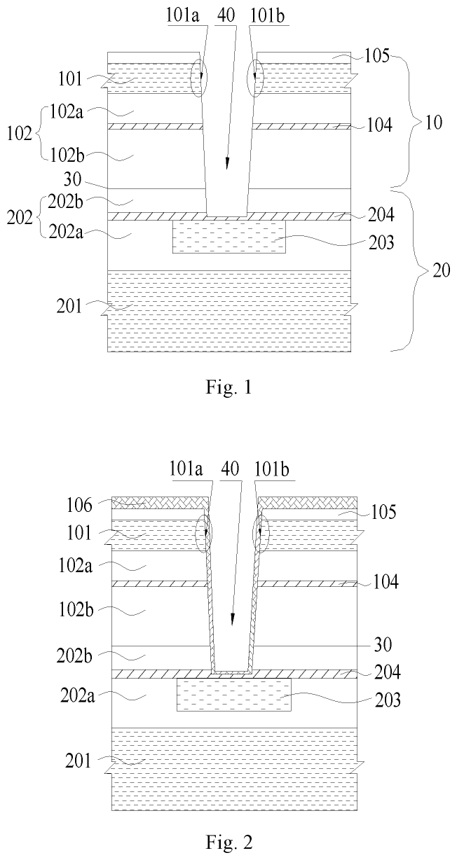

Next, as shown in FIG. 2, an isolation layer 106 is formed for protecting the exposed portions 101a and 101b of the first substrate 101, the isolation layer 106 covering the surfaces of the deep hole 40 and the oxide layer 105.

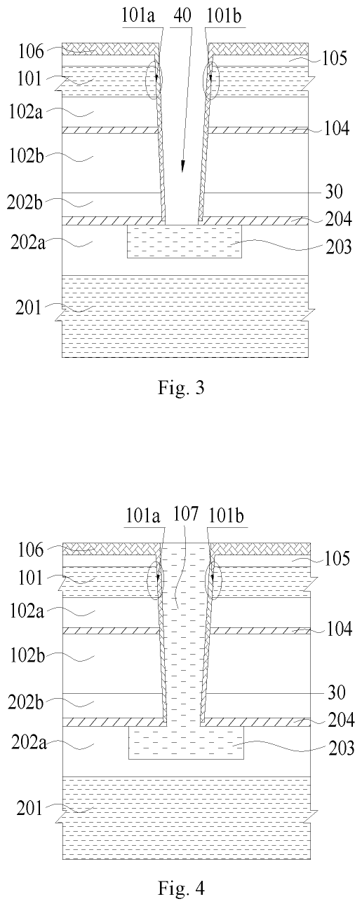

Next, as shown in FIG. 3, a dry etching process is performed to remove a portion of the isolation layer 106 and a portion of the second etching stopping layer 204 at the bottom of the deep hole 40 so as to expose the second metal layer 203.

Next, as shown in FIG. 4, an interconnection layer 107 is formed, the deep hole 40 being filled with the interconnection layer 107 and the interconnection layer 107 covering the surface of the isolation layer 106, and then a chemical mechanical polishing process is performed to remove a portion of the interconnection layer on the surface of the isolation layer 106.

With continued reference to FIG. 4, the interconnection layer 107 is electrically connected to the second metal layer 203 via the deep hole 40, and the interconnection layer 107 leads the second metal layer 203 out by electrical connection and interconnects with the first metal layer of the upper wafer 10.

However, the inventors have found that, as shown in FIG. 3 and FIG. 4, on the one hand, the isolation layer 106 shielding the exposed portions 101a and 101b of the first substrate 101 may be continuously thinned in the dry etching process for exposing the second metal layer 203, and the thinning may cause the interconnection layer 107 to diffuse from the exposed portions 101a and 101b of the first substrate 101 into the first substrate 101 of the upper wafer; and on the other hand, the thinned isolation layer 106 is easily damaged by the heat-treated interconnection layer 107, causing the metal of the interconnection layer 107 to diffuse into the first substrate 101, and causing electrical anomalies, etc., thereby lowering the yield and performance of the wafer.

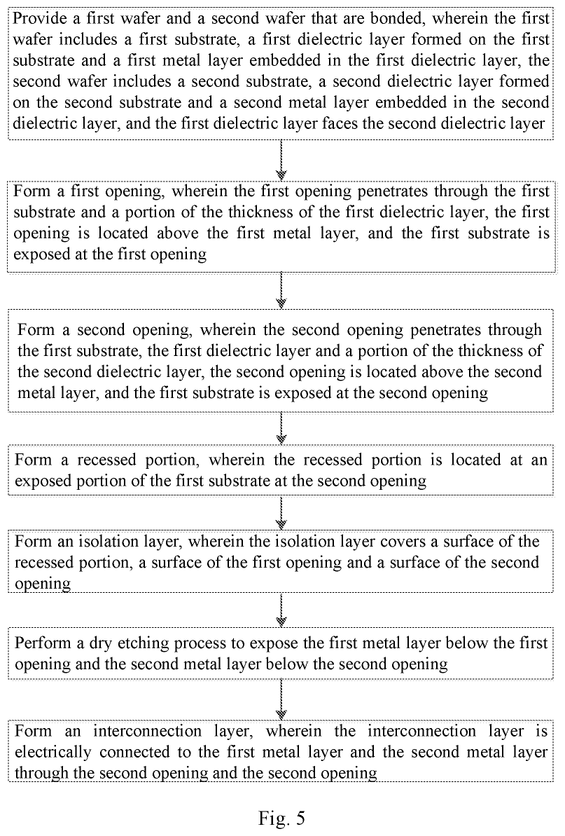

Based on the above research, an embodiment of the present invention provides a manufacturing method of a semiconductor device. As shown in FIG. 5, the method includes:

providing a first wafer and a second wafer that are bonded, wherein the first wafer includes a first substrate, a first dielectric layer formed on the first substrate and a first metal layer embedded in the first dielectric layer, the second wafer includes a second substrate, a second dielectric layer formed on the second substrate and a second metal layer embedded in the second dielectric layer, and the first dielectric layer faces the second dielectric layer;

forming a first opening, wherein the first opening penetrates through the first substrate and a portion of the thickness of the first dielectric layer, the first opening is located above the first metal layer, and the first substrate is exposed at the first opening;

forming a second opening, wherein the second opening penetrates through the first substrate, the first dielectric layer and a portion of the thickness of the second dielectric layer, the second opening is located above the second metal layer, and the first substrate is exposed at the second opening;

forming a recessed portion, wherein the recessed portion is located at an exposed portion of the first substrate at the second opening;

forming an isolation layer, wherein the isolation layer covers a surface of the recessed portion, a surface of the first opening and a surface of the second opening;

performing a dry etching process to expose the first metal layer below the first opening and the second metal layer below the second opening; and

forming an interconnection layer, wherein the interconnection layer is electrically connected to the first metal layer and the second metal layer via the first opening and the second opening.

It should be noted that this embodiment does not limit the order of forming the first opening and forming the second opening. The first opening may be formed before the second opening is formed; or the second opening may be formed before the first opening is formed.

In this specification, “upper wafer” and “lower wafer” are only a relative concept. When stacking, there is always one wafer at the upper portion and the other wafer at the lower portion. However, the present invention does not limit which wafer of the first wafer and the second wafer must be placed above/below, and the positions of the upper and lower wafers can be interchanged. Herein, for the sake of simplicity and convenience of description, only one positional relationship of the two wafers is shown. Those skilled in the art can understand that all the technical contents described herein are also applicable to the case where the positions of the “first wafer” and the “second wafer” are reversed up and down. At this time, the positional relationship of the layers of the stacked semiconductor device is also reversed up and down accordingly. In some cases, preferably, during a bonding process on two wafers, a wafer having a relatively large wafer bow is placed below. However, in this case, after the wafer bonding is completed, it is also possible to determine whether to reverse up and down according to actual needs, thereby ultimately determining which wafer is above and which wafer is below.

It is to be noted that the terms “first”, “second”, “third”, “fourth” and the like are used herein to distinguish different components or techniques having the same name, and do not mean a sequence or a positional relationship or the like. In addition, for different components having the same name, such as “first substrate” and “second substrate”, “first dielectric layer” and “second dielectric layer”, etc., it does not mean that they have the same structure or components. For example, although not shown in the drawings, in most cases, the components formed in the “first substrate” and the “second substrate” are different, and the structures of the substrates may be different. In some implementations, the substrate may be a semiconductor substrate made of any semiconductor material (e.g., Si, SiC, SiGe, etc.) suitable for a semiconductor device. In other implementations, the substrate may also be a composite substrate such as silicon-on-insulator (SOI), silicon germanium-on-insulator, or the like. Those skilled in the art will understand that the substrate is not subject to any restrictions, but may be selected according to practical applications. Various devices (not limited to semiconductor devices) members (not shown) may be formed in the substrate. The substrate may also have been formed with other layers or members, such as gate structures, contact holes, dielectric layers, metal wires, through holes, and the like.

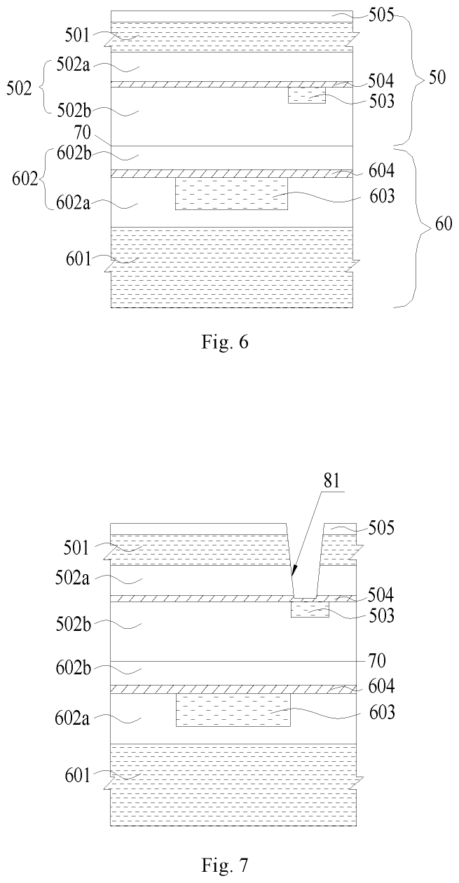

The semiconductor device and the manufacturing method thereof of the present invention will be further described in detail below with reference to FIGS. 6-16. Advantages and features of the present invention will become more apparent from the description. It should be noted that the drawings are in a very simplified form and are used in a non-precise scale, and are merely for convenience and clarity of the purpose of the embodiments of the present invention.

First, as shown in FIG. 5 and FIG. 6, a first wafer 50 and a second wafer 60 that are bonded are provided. The first wafer 50 includes a first substrate 501, a first dielectric layer 502 formed on the first substrate 501 and a first metal layer 503 embedded in the first dielectric layer 502. The second wafer 60 includes a second substrate 601, a second dielectric layer 602 formed on the second substrate 601 and a second metal layer 603 embedded in the second dielectric layer 602. The first dielectric layer 502 faces the second dielectric layer 602.

The first dielectric layer 502 includes a first dielectric layer first portion 502a and a first dielectric layer second portion 502b, and the first metal layer 503 is embedded between the first dielectric layer first portion 502a and the first dielectric layer second portion 502b. The second dielectric layer 602 includes a second dielectric layer first portion 602a and a second dielectric layer second portion 602b, and the second metal layer 603 is embedded between the second dielectric layer first portion 602a and the second dielectric layer second portion 602b.

In a preferred embodiment, the first wafer 50 further includes a first etching stopping layer 504. The first etching stopping layer 504 is located between the first metal layer 503 and the first dielectric layer first portion 502a. The second wafer 60 further includes a second etching stopping layer 604. The second etching stopping layer 604 is located between the second metal layer 603 and the second dielectric layer second portion 602b. The first wafer 50 further includes an oxide layer 505 located on the back surface of the first substrate 501.

Next, as shown in FIG. 5 and FIG. 7, an etching process is performed to form a first opening 81. The etching stops at the first etching stopping layer 504. The first opening 81 penetrates through the first substrate 501 and a portion of the thickness of the first dielectric layer 502, the first opening 81 is located above the first metal layer 503, and the first substrate 501 is exposed at the first opening 81.

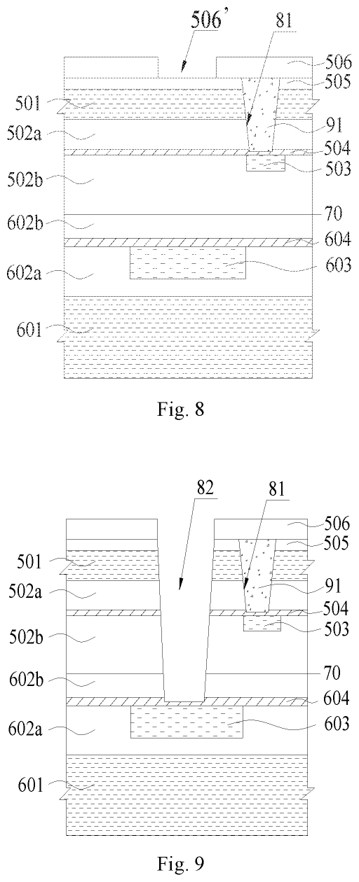

After the first opening 81 is formed, as shown in FIG. 8, a filling layer 91 is formed, the first opening 81 is filled with the filling layer 91 and the filling layer 91 covers the surface of the oxide layer 505. Then, a back etching process is performed to remove the filling layer 91 on the surface of the oxide layer 505, leaving only the filling layer 91 in the first opening 81.

Here, the filling layer 91 may be an organic solvent BARC (Bottom Anti Reflective Coating).

As shown in FIG. 8 and FIG. 9, a patterned photoresist layer 506 is formed on the surface of the oxide layer 505, the patterned photoresist layer 506 defining a photoresist opening 506′ above the oxide layer 505. An etching process is performed by using the patterned photoresist layer 506 as a mask, and the etching stops at the second etching stopping layer 604 to form a second opening 82. The second opening 82 penetrates through the oxide layer 505, the first substrate 501, the first dielectric layer 502 and a portion of the thickness of the second dielectric layer 602. The second opening 82 is located above the second metal layer 603. The first substrate 501 is exposed at the second opening 82. The shape of the cross section of the second opening 82 perpendicular to the surfaces of the first wafer 50 and the second wafer 60 is an inverted trapezoid. The use of the inverted trapezoidal opening facilitates subsequent filling in the opening.

It should be noted that this embodiment does not limit the order of forming the first opening and forming the second opening. The first opening may be formed before the second opening is formed as shown in FIG. 7 to FIG. 9; or the second opening may be formed before the first opening is formed by using the same method.

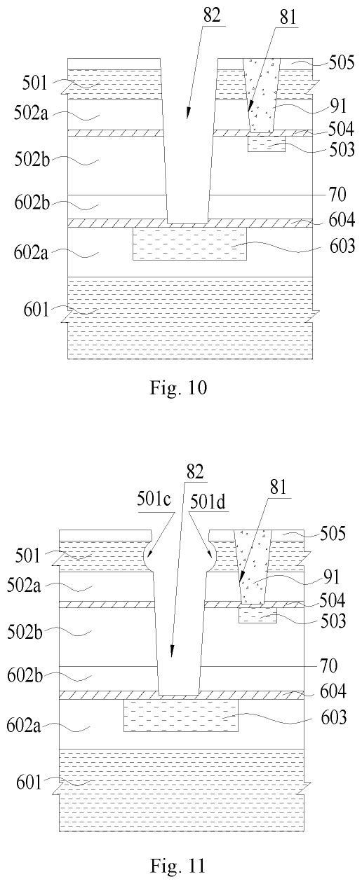

As shown in FIG. 10, the patterned photoresist layer 506 on the surface of the oxide layer 505 is removed.

Next, as shown in FIG. 11, an etching process is performed to form a recessed portion. The exposed portion of the first substrate 501 at the second opening 82 is etched, such that the exposed portion is recessed toward the two sides of the second opening 82 to form recessed portions 501c and 501d of the first substrate 501 on the two sides of the second opening 82. In this embodiment, the recessed portions 501c and 501d are both arcuate recessed portions, that is, the shape of the longitudinal section of the recessed portions 501c and 501d is a semicircle, a semiellipse or a semi-convex circle.

The etching for forming the recessed portions may be dry etching, in which an etching gas having a selective etching effect on the first substrate 501 is used to avoid etching other positions. The etching may also be wet etching, in which a solution having a selective etching effect on the first substrate 501 is selected. By taking the first substrate 501 as a silicon substrate as an example, for example, an alkaline solution may be selected such that only the exposed first substrate 501 is etched to some extent. The specific etching time of the etching process may depend on the depth of the recessed portion to be formed, and is not limited in the present invention.

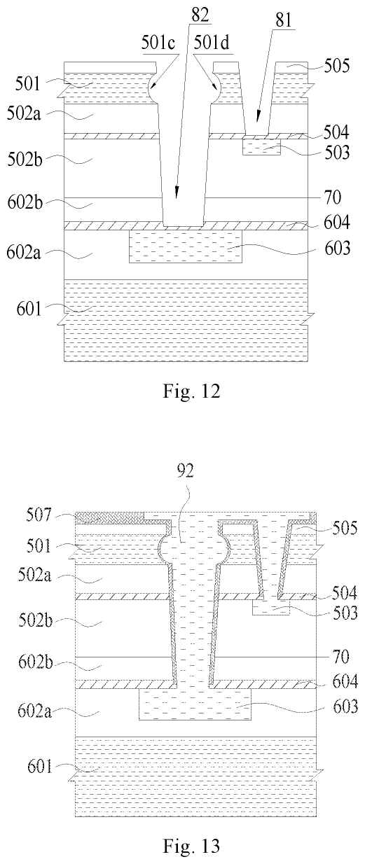

Next, as shown in FIG. 12, the filling layer 91 in the first opening 81 is removed.

Next, as shown in FIG. 13, an isolation layer 507 is further formed to protect the recessed portions 501c and 501d of the first substrate 501.

The isolation layer 507 covers the surfaces of the recessed portions 501c and 501d, the first opening 81, the second opening 82 and the oxide layer 505. The material of the isolation layer 507 is, for example, silicon oxide, which can be formed by a chemical vapor deposition process.

Thereafter, a dry etching process is performed to etch away the first etching stopping layer 504 at the bottom of the first opening 81 and the second etching stopping layer 604 at the bottom of the second opening 82 to expose the first metal layer 503 below the first opening 81 and the second metal layer 603 below the second opening 82. Since the dry etching has directivity, the isolation layer 507 of the recessed portion is not easily damaged.

Finally, as shown in FIG. 13, an interconnection layer 92 is formed. The interconnection layer 92 is electrically connected to the first metal layer 503 and the second metal layer 603 via the first opening 81 and the second opening 82. The interconnection layer 92 is a conductive material, which may be copper or a copper alloy. The first opening 81 and the second opening 82 may be filled by copper electroplating, and planarization is performed.

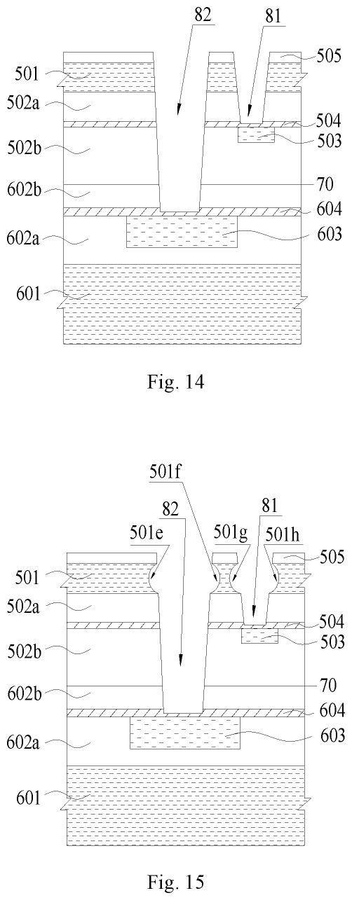

The above description is made by forming the recessed portion only in the second opening 82. In the specific embodiment, the recessed portions may be formed in both the first opening 81 and the second opening 82. The details will be described below with reference to FIGS. 14-16.

As shown in FIG. 10, the patterned photoresist layer 506 on the surface of the oxide layer 505 is removed.

Next, as shown in FIG. 14, the filling layer 91 in the first opening 81 is removed.

Next, as shown in FIG. 15, an etching process is performed to form a recessed portion, and the exposed portions of the first substrate 501 at the first opening 81 and the second opening 82 are etched; the exposed portion of the first substrate 501 at the second opening 82 is recessed toward the two sides of the second opening 82 to form recessed portions 501e and 501f; and the exposed portion of the first substrate 501 at the first opening 81 is recessed toward the two sides of the first opening 81 to form recessed portions 501g and 501h. In this embodiment, the recessed portions 501e, 501f, 501g and 501h are arcuate recessed portions, that is, the shape of the longitudinal section of the recessed portions 501e, 501f, 501g and 501h are a semicircle, a semiellipse or a semi-convex circle.

The etching for forming the recessed portions may be dry etching, in which an etching gas having a selective etching effect on the first substrate 501 is used to avoid etching other positions. The etching may also be wet etching, in which a solution having a selective etching effect on the first substrate 501 is selected. By taking the first substrate 501 as a silicon substrate as an example, for example, an alkaline solution may be selected such that only the exposed first substrate 501 is etched to some extent. The specific etching time of the etching process may depend on the depth of the recessed portion to be formed, and is not limited in the present invention.

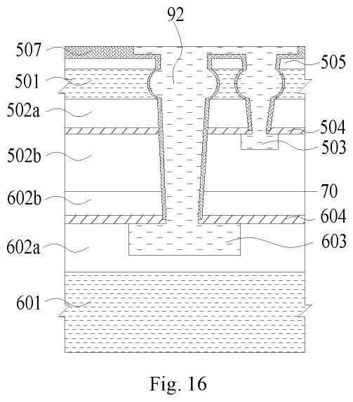

Next, as shown in FIG. 15 and FIG. 16, an isolation layer 507 is first formed to protect the recessed portions 501e, 501f, 501g and 501h of the first substrate 501, the isolation layer 507 covering the surfaces of the recessed portions 501e, 501f, 501g and 501h, the first opening 81, the second opening 82 and the oxide layer 505. The material of the isolation layer 507 is, for example, silicon oxide, which can be formed by a chemical vapor deposition process.

Thereafter, an etching process is performed to etch away the first etching stopping layer 504 at the bottom of the first opening 81 and the second etching stopping layer 604 at the bottom of the second opening 82 to expose the first metal layer 503 below the first opening 81 and the second metal layer 603 below the second opening 82.

Finally, an interconnection layer 92 is formed. As shown in FIG. 16, the interconnection layer 92 is electrically connected to the first metal layer 503 and the second metal layer 603 via the first opening 81 and the second opening 82. The interconnection layer 92 is a conductive material, which may be copper or a copper alloy. The first opening 81 and the second opening 82 may be filled by copper electroplating, and planarization is performed.

The embodiment of the present invention further provides a semiconductor device, as shown in FIG. 12 and FIG. 13, including:

a first wafer 50 and a second wafer 60, wherein the first wafer 50 includes a first substrate 501, a first dielectric layer 502 formed on the first substrate 501 and a first metal layer 503 embedded in the first dielectric layer 502. The second wafer 60 includes a second substrate 601, a second dielectric layer 602 formed on the second substrate 601 and a second metal layer 603 embedded in the second dielectric layer 602. The first dielectric layer 502 faces the second dielectric layer 602;

a first opening 81 and a second opening 82, wherein the first opening 81 penetrates through the first substrate 501 and a portion of the thickness of the first dielectric layer 502. The first opening 81 is located above the first metal layer 503, and the first substrate 501 is exposed at the first opening 81. The second opening 82 penetrates through the first substrate 501, the first dielectric layer 502 and a portion of the thickness of the second dielectric layer 602. The second opening 82 is located above the second metal layer 603, and the first substrate 501 is exposed at the second opening 82;

recessed portions 501c and 501d, wherein the recessed portions 501c and 501d are located at the exposed portion of the first substrate 501 at the second opening 82. The recessed portions 501c and 501d are, for example, arcuate recessed portions, that is, the shape of the longitudinal section of the recessed portions 501c and 501d is a semicircle, a semiellipse or a semi-convex circle;

an isolation layer 507, wherein the isolation layer 507 covers the surfaces of the recessed portions 501c and 501d, the first opening 81, the second opening 82 and the oxide layer 505. The material of the isolation layer 507 is, for example, silicon oxide; and

an interconnection layer 92 formed in the first opening 81 and the second opening 82, wherein the interconnection layer 92 is electrically connected to the first metal layer 503 and the second metal layer 603.

The embodiment of the present invention further provides a semiconductor device, as shown in FIG. 15 and FIG. 16, including:

a first wafer 50 and a second wafer 60, wherein the first wafer 50 includes a first substrate 501, a first dielectric layer 502 formed on the first substrate 501 and a first metal layer 503 embedded in the first dielectric layer 502. The second wafer 60 includes a second substrate 601, a second dielectric layer 602 formed on the second substrate 601 and a second metal layer 603 embedded in the second dielectric layer 602, and the first dielectric layer 502 faces the second dielectric layer 602;

a first opening 81 and a second opening 82, wherein the first opening 81 penetrates through the first substrate 501 and a portion of the thickness of the first dielectric layer 502. The first opening 81 is located above the first metal layer 503, and the first substrate 501 is exposed at the first opening 81. The second opening 82 penetrates through the first substrate 501, the first dielectric layer 502 and a portion of the thickness of the second dielectric layer 602. The second opening 82 is located above the second metal layer 603, and the first substrate 501 is exposed at the second opening 82;

recessed portions 501e, 501f, 501g and 501h, wherein the recessed portions 501e and 501f are located at the exposed portion of the first substrate 501 at the second opening 82, and the recessed portions 501g and 501h are located at the exposed portion of the first substrate 501 at the first opening 81. The recessed portions 501e, 501f, 501g and 501h are, for example, arcuate recessed portions, that is, the shape of the longitudinal section of the recessed portions 501e, 501f, 501g and 501h are a semicircle, a semiellipse or a semi-convex circle;

an isolation layer 507, wherein the isolation layer 507 covers the surfaces of the recessed portions 501e, 501f, 501g and 501h, the first opening 81, the second opening 82 and the oxide layer 505. The material of the isolation layer 507 is, for example, silicon oxide; and

an interconnection layer 92 formed in the first opening 81 and the second opening 82, wherein the interconnection layer 92 is electrically connected to the first metal layer 503 and the second metal layer 603.

As shown in FIG. 6, FIG. 13 and FIG. 16, the first wafer 50 includes a first substrate 501, a first dielectric layer 502 and a first metal layer 503. The second wafer 60 includes a second substrate 601, a second dielectric layer 602 and a second metal layer 603, and the first dielectric layer 502 faces the second dielectric layer 602.

The first dielectric layer 502 includes a first dielectric layer first portion 502a and a first dielectric layer second portion 502b, and the first metal layer 503 is embedded between the first dielectric layer first portion 502a and the first dielectric layer second portion 502b. The second dielectric layer 602 includes a second dielectric layer first portion 602a and a second dielectric layer second portion 602b, and the second metal layer 603 is embedded between the second dielectric layer first portion 602a and the second dielectric layer second portion 602b.

In a preferred embodiment, the first wafer 50 further includes a first etching stopping layer 504, and the first etching stopping layer 504 is located between the first metal layer 503 and the first dielectric layer first portion 502a. The second wafer 60 further includes a second etching stopping layer 604, and the second etching stopping layer 604 is located between the second metal layer 603 and the second dielectric layer second portion 602b. The first wafer 50 further includes an oxide layer 505 located on the back surface of the first substrate 501.

It should be noted that although only the electrical connection structure between two metal layers of the semiconductor device is shown in the drawing, those skilled in the art will appreciate that at least one such electrical connection structure between the two metal layers is formed between the two wafers for realizing metal interconnection.

In summary, according to the present invention, after the second opening is formed, the first substrate exposed by the second opening is etched such that the exposed first substrate is recessed toward the two sides of the second opening, and then an isolation layer covering the sidewall of the second opening and the recessed portion is formed to effectively prevent the isolation layer from being damaged during the subsequent dry etching process and ensure that the isolation layer has a function of isolating the interconnection layer in the subsequent process, thereby improving the yield and performance of the device.

The above description is only for the description of the preferred embodiments of the present invention, and is not intended to limit the scope of the present invention. Any changes and modifications made by those skilled in the art in light of the above disclosure are all within the scope of the appended claims.

What is claimed is:

1. A manufacturing method of a semiconductor device, comprising:
providing a first wafer and a second wafer, wherein the first wafer comprises a first substrate, a first dielectric layer formed on the first substrate and a first metal layer embedded in the first dielectric layer, the second wafer comprises a second substrate, a second dielectric layer formed on the second substrate and a second metal layer embedded in the second dielectric layer, and the first dielectric layer and the second dielectric layer being bonded to each other;
forming a first opening, wherein the first opening penetrates through the first substrate and a portion of the first dielectric layer, the first opening located above the first metal layer, and the first substrate being exposed at the first opening;
forming a second opening, wherein the second opening penetrates through the first substrate, the first dielectric layer and a portion of the second dielectric layer, the second opening located above the second metal layer, and the first substrate being exposed at the second opening;
forming recessed portions, wherein the recessed portions are located at an exposed portion of the first substrate at the second opening;
forming an isolation layer, wherein the isolation layer covers surfaces of the recessed portions, a surface of the first opening and a surface of the second opening;
performing a dry etching process to expose a portion of the first metal layer below the first opening and a portion of the second metal layer below the second opening; and
forming an interconnection layer, wherein the interconnection layer is electrically connected to the first metal layer via the first opening and electrically connected to the second metal layer via the second opening.

2. The manufacturing method of a semiconductor device according to claim 1, wherein the recessed portions are further located at an exposed portion of the first substrate at the first opening.

3. The manufacturing method of a semiconductor device according to claim 1, wherein forming the recessed portions comprises performing a dry etching process to make the first substrate to be recessed toward two sides of the second opening at the exposed portion of the second opening.

4. The manufacturing method of a semiconductor device according to claim 1, wherein forming the recessed portions comprises performing a wet etching process to make the first substrate to be recessed toward two sides of the second opening at the exposed portion of the second opening.

5. The manufacturing method of a semiconductor device according to claim 1, after forming the first opening and before forming the second opening, wherein the manufacturing method further comprises:
forming a filling layer, wherein the first opening is filled with the filling layer and the filling layer covers a surface of the first wafer; and
performing a back etching process to remove a portion of the filling layer on the surface of the first wafer.

6. The manufacturing method of a semiconductor device according to claim 1, wherein the recessed portions are arcuate recesses, and a longitudinal section of each of the recessed portions has a shape of a semicircle, a semiellipse or a semi-convex circle.

7. The manufacturing method of a semiconductor device according to claim 1, wherein a cross section of the first opening perpendicular to a surface of the first wafer has a shape of an inverted trapezoid and the second opening perpendicular to a surface of the second wafer has a shape of an inverted trapezoid.

8. The manufacturing method of a semiconductor device according to claim 1, wherein the first dielectric layer comprises a first dielectric layer first portion and a first dielectric layer second portion, and the first metal layer is embedded between the first dielectric layer first portion and the first dielectric layer second portion; the second dielectric layer comprises a second dielectric layer first portion and a second dielectric layer second portion, and the second metal layer is embedded between the second dielectric layer first portion and the second dielectric layer second portion.

9. The manufacturing method of a semiconductor device according to claim 8, wherein the first wafer further comprises a first etching stopping layer, and the first etching stopping layer is located between the first metal layer and the first dielectric layer first portion; and the second wafer further comprises a second etching stopping layer, and the second etching stopping layer is located between the second metal layer and the second dielectric layer second portion.

10. The manufacturing method of a semiconductor device according to claim 1, wherein the first wafer further comprises an oxide layer located on a surface of the first substrate facing away from the first dielectric layer.

11. The manufacturing method of a semiconductor device according to claim 1, wherein the filling layer is formed of an organic solvent Bottom Anti Reflective Coating.

12. The manufacturing method of a semiconductor device according to claim 1, wherein the isolation layer is formed of silicon oxide and is formed by a chemical vapor deposition process.

13. A semiconductor device, comprising:
a first wafer and a second wafer, wherein the first wafer comprises a first substrate, a first dielectric layer formed on the first substrate and a first metal layer embedded in the first dielectric layer, the second wafer comprises a second substrate, a second dielectric layer formed on the second substrate and a second metal layer embedded in the second dielectric layer, and the first dielectric layer and the second dielectric layer being bonded to each other;
a first opening and a second opening, wherein the first opening penetrates through the first substrate and a portion of the first dielectric layer, the first opening is located above the first metal layer, and the first substrate being exposed at the first opening; and the second opening penetrates through the first substrate, the first dielectric layer and a portion of the second dielectric layer, the second opening is located above the second metal layer, and the first substrate being exposed at the second opening;
recessed portions, wherein the recessed portions are located at an exposed portion of the first substrate at least at one of the first opening and the second opening;
an isolation layer, wherein the isolation layer covers surfaces of the recessed portions, a surface of the first opening and a surface of the second opening; and
an interconnection layer formed in the first opening and the second opening, wherein the interconnection layer is electrically connected to the first metal layer via the first opening and electrically connected to the second metal layer via the second opening.

14. The semiconductor device according to claim 13, wherein the recessed portions are located at an exposed portion of the first substrate at both of the first opening and the second opening.

15. The semiconductor device according to claim 13, wherein the recess portions are arcuate recesses and a longitudinal section of each of the recessed portions has a shape of a semicircle, a semiellipse or a semi-convex circle.

16. The semiconductor device according to claim 13, wherein a cross section of the first opening perpendicular to a surface of the first wafer has a shape of an inverted trapezoid and the second opening perpendicular to a surface of the second wafer has a shape of an inverted trapezoid.

17. The semiconductor device according to claim 13, wherein the first dielectric layer comprises a first dielectric layer first portion and a first dielectric layer second portion, and the first metal layer is embedded between the first dielectric layer first portion and the first dielectric layer second portion; the second dielectric layer comprises a second dielectric layer first portion and a second dielectric layer second portion, and the second metal layer is embedded between the second dielectric layer first portion and the second dielectric layer second portion.

18. The semiconductor device according to claim 17, wherein the first wafer further comprises a first etching stopping layer, and the first etching stopping layer is located between the first metal layer and the first dielectric layer first portion; and the second wafer further comprises a second etching stopping layer, and the second etching stopping layer is located between the second metal layer and the second dielectric layer second portion.

19. The semiconductor device according to claim 13, wherein the first wafer further comprises an oxide layer located on a surface of the first substrate facing away from the first dielectric layer.

20. The semiconductor device according to claim 13, wherein the isolation layer is formed of silicon oxide and is formed by a chemical vapor deposition process.
